(19) United States
(12) Patent Application Publication
(10) Pub. No.: US 2023/0120214 A1
(43) Pub. Date: Apr. 20, 2023

(54) METHOD FOR CONTROLLING WET ETCH RATE (WER) SELECTIVITY

(71) Applicant: ASM IP Holding B.V., Almere (NL)

(72) Inventor: Takashi Mizoguchi, Tokyo (JP)

(21) Appl. No.: 17/965,559

(22) Filed: Oct. 13, 2022

Related U.S. Application Data
(60) Provisional application No. 63/256,937, filed on Oct. 18, 2021.

(51) Int. Cl. H01L 21/02; H01L 21/311; C23C 16/34; C23C 16/56; C23C 16/455; C23C 16/50

(52) U.S. Cl. CPC H01L 21/0217; H01L 21/0228; H01L 21/02211; H01L 21/31111; C23C 16/345; C23C 16/56; C23C 16/45536; C23C 16/50; C23C 16/45553

(57) ABSTRACT

A process for forming layered structures using plasma enhanced atomic layer deposition (PEALD) to deposit a TS-SiN film on trenches (or space and line patterns) of a substate. The SiN deposition process is adapted to form a TS-SiN film by controlling the argon to nitrogen flow ratio during deposition cycles such as by tuning the ratio of a first gas to a second gas provided continuously during PEALD deposition. The SiN film has etching selectivity between horizontal and vertical portions of the film and also etching selectivity between films at top and bottom portions of the patterns or trenches, e.g., with a portion of the thin film at the bottom of the pattern or trench having a higher WER than the thin film at the top of the pattern or trench. Wet etching may then be used to selectively etch material from the thin film in a topologically selective manner.

### CROSS-REFERENCE TO RELATED APPLICATIONS

This application claims priority to U.S. Provisional Patent Application Ser. No. 63/256,937 filed Oct. 18, 2021, and titled METHOD FOR CONTROLLING WET ETCH RATE (WER) SELECTIVITY, the disclosure of which is hereby incorporated by reference in its entirety.

### FIELD OF THE DISCLOSURE

The present disclosure relates generally semiconductor manufacturing and corresponding systems for performing the manufacturing, and, more particularly, to a method for fabricating a layer structure including a silicon nitride film in or on trenches by controlling the wet etch rate (WER) selectivity in a topological manner.

### BACKGROUND OF THE DISCLOSURE

In manufacturing processes of large-scale integrated circuits (LSIs), there are several processes for forming sidewalls in trenches. The sidewalls are used as spacers or used for blocking etching of a structure from side surfaces of trenches. Conventionally, the sidewalls were formed by forming a conformal film on surfaces of trenches and then by removing portions thereof formed on an upper surface in which the trenches were formed and portions formed on bottom surfaces of the trenches by asymmetrical etching. However, when such a formation method is used, over-etching is required in order to remove footing of sidewalls in which the thickness of the sidewalls increases near and at the bottom, forming a slope. Over-etching causes etching of an underlying layer and causes damage to a layer structure.

Any discussion of problems and solutions set forth in this section has been included in this disclosure solely for the purpose of providing a context for the present disclosure and should not be taken as an admission that any or all of the discussion was known at the time the invention was made.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

Processes exist for forming a thin film of silicon nitride (SiN) on a pattern or on a surface with trenches such that the thin film is topologically selective (TS). Then, the TS-SiN film is etched using wet etching, such as with diluted hydrofluoric acid (dHF) liquid, to leave a side film or a film on sidewalls of the pattern or to leave the top and bottom portions of the film on the pattern. In some cases, these processes were specifically designed to use different chemical resistance qualities between the TS-SiN film on the horizonal surfaces the TS-SiN film on the vertical surfaces or sidewalls of the trenches. The inventor recognized that this can be useful in many applications, but it may be desirable to design other processes to create a Ti—SiN film because the chemical resistance-based techniques often require extra optimization work, e.g., optimization of wet etching conditions related to the film thickness and the like.

The inventor further recognized that a TS-SiN film can be formed on a pattern (e.g., on surfaces of trenches on an upper surface of a substrate or wafer) by tuning the film forming process rather than the etching process. Briefly, the new process for forming layered structures may involve using plasma enhanced atomic layer deposition (PEALD) to deposit a TS-SiN film on trenches (or space and line patterns) of a substate. The SiN deposition process is adapted to form a TS-SiN film by controlling the argon (Ar) to nitrogen (N₂) flow ratio during deposition cycles (e.g., by controlling or tuning the ratio of a first carrier gas to a second carrier gas provided continuously during PEALD deposition). The formed SiN film will have etching selectivity between horizontal and vertical portions of the film (e.g., with vertical or sidewall portion having a higher wet etch rate (WER)) and also etching selectivity between films at top and bottom portions of the patterns or trenches (e.g., with a portion of the thin film at the bottom of the pattern or trench having a higher WER than a portion of the thin film at the top of the pattern or trench). Wet etching, such as with dHF, may then be used to selectively etch or remove material from the thin film in a topologically selective manner.

According to some aspects of the description, a method is provided for fabricating a layer structure. The method includes providing a substrate in a reaction chamber, and the substrate may include, on an upper surface, a trench with a top surface, a bottom surface, and sidewalls. The method further includes providing a carrier gas flow to the reaction chamber, with the carrier gas flow including a first carrier gas and a second carrier gas. During the step of providing the carrier gas flow, the method includes forming a dielectric film containing a Si—N bond on the upper surface of the substrate. Then, after the step of forming the dielectric film, the method includes removing with etching at least a portion of the dielectric film on at least one of the sidewalls, the top surface, and the bottom surface. The etching may have a first rate for the portion of the dielectric film on the sidewalls, a second rate for the portion of the dielectric film on the bottom surface, and a third rate for the portion of the dielectric film on the top surface. In practicing the method, the first, second, and third rates for the etching are defined at least in part by a ratio of the first carrier gas to the second carrier gas.

In some implementations of the method, the step of forming the dielectric film includes a cyclic plasma deposition process such as PEALD or PECVD. In such cases, a cycle of the cyclic plasma deposition process may include contacting the upper surface of the substrate with a precursor selected from the group consisting of H₂SiCl₂, hexachlorodisilane, trichlorosilane, trichlorosilane (HSiCl₃), and chlorosilane (H₃SiCl) and contacting the upper surface of the substrate with a reactant selected from the group consisting of H₂, NH₃, N₂H₄, and N₂H₂.

In some embodiments, the first carrier gas includes argon (Ar) and the second carrier gas includes nitrogen (N₂). In these or other embodiments of the method, the etching step may include or involve wet etching, and the first rate for the etching for the portion of the dielectric film on the sidewalls can be greater than the second rate for the etching for the portion of the dielectric film on the bottom surface. Further, to implement the method, the second rate for the etching for the portion of the dielectric film on the bottom surface can be greater than the third rate for the etching for the portion of the dielectric film on the top surface.

To implement the method, the ratio of the first carrier gas to the second carrier gas can be controlled to be in the range of 0 to 4. For example, the ratio of the first carrier gas to the second carrier gas may be less than 0.3 while some examples have set the ratio to 0.36, to 4, and to a value greater than 4 to achieve desirable results.

For the purpose of summarizing the disclosure and the advantages achieved over the prior art, certain objects and advantages of the disclosure have been described herein above. Of course, it is to be understood that not necessarily all such objects or advantages may be achieved in accordance with any particular embodiment of the disclosure. Thus, for example, those skilled in the art will recognize that the embodiments disclosed herein may be carried out in a manner that achieves or optimizes one advantage or group of advantages as taught or suggested herein without necessarily achieving other objects or advantages as may be taught or suggested herein.

All of these embodiments are intended to be within the scope of the disclosure. These and other embodiments will become readily apparent to those skilled in the art from the following detailed description of certain embodiments having reference to the attached figures, the disclosure not being limited to any particular embodiment(s) discussed.

### BRIEF DESCRIPTION OF THE DRAWING FIGURES

While the specification concludes with claims particularly pointing out and distinctly claiming what are regarded as embodiments of the disclosure, the advantages of embodiments of the disclosure may be more readily ascertained from the description of certain examples of the embodiments of the disclosure when read in conjunction with the accompanying drawings. Elements with the like element numbering throughout the figures are intended to be the same.

FIG. 1A is schematic representation of a plasma enhanced atomic layer deposition (PEALD) apparatus for depositing a thin film or layer of material that is usable in an embodiment of the present description.

FIG. 1B illustrates a schematic representation of a gas supply system using a flow-pass system (FPS) usable in an embodiment of the present description including the apparatus of FIG. 1A.

FIG. 2 is a flow diagram of an exemplary process for fabricating a layered structure including forming a topologically selective (TS) thin film to enhance selective material removal with wet etching.

FIG. 3 is a graph illustrating steps within a cycle of a thin film deposition of the present description such as the process of FIG. 2.

FIG. 4 is a schematic representation of deposition and etch processes for fabricating a layered structure with a thin film formed to have differing wet etch rates (WERs) in differing topological areas.

### DETAILED DESCRIPTION

Although certain embodiments and examples are disclosed below, it will be understood by those in the art that the disclosure extends beyond the specifically disclosed embodiments and/or uses of the disclosure and obvious modifications and equivalents thereof. Thus, it is intended that the scope of the disclosure should not be limited by the particular embodiments described herein.

The illustrations presented herein are not meant to be actual views of any particular material, apparatus, structure, or device, but are merely representations that are used to describe embodiments of the disclosure.

In this disclosure, “gas” may include vaporized solid and/or liquid and may be constituted by a single gas or a mixture of gases. In this disclosure, a process gas introduced to a reaction chamber through a showerhead may be comprised of, consist essentially of, or consist of a precursor gas and an additive gas. The precursor gas and the additive gas are typically introduced as a mixed gas or separately to a reaction space. The precursor gas can be introduced with a carrier gas such as a noble gas. The additive gas may be comprised of, consist essentially of, or consist of a reactant gas and a dilution gas such as a noble gas. The reactant gas and the dilution gas may be introduced as a mixed gas or separately to the reaction space. A precursor may be comprised of two or more precursors, and a reactant gas may be comprised of two or more reactant gases. The precursor is a gas chemisorbed on a substrate and typically containing a metalloid or metal element which constitutes a main structure of a matrix of a dielectric film, and the reactant gas for deposition is a gas reacting with the precursor chemisorbed on a substrate when the gas is excited to fix an atomic layer or monolayer on the substrate. “Chemisorption” refers to chemical saturation adsorption. A gas other than the process gas, i.e., a gas introduced without passing through the showerhead, may be used for, e.g., sealing the reaction space, which includes a seal gas such as a noble gas. In some embodiments, “film” refers to a layer continuously extending in a direction perpendicular to a thickness direction substantially without pinholes to cover an entire target or concerned surface, or simply a layer covering a target or concerned surface. In some embodiments, “layer” refers to a structure having a certain thickness formed on a surface or a synonym of film or a non-film structure. A film or layer may be constituted by a discrete single film or layer having certain characteristics or multiple films or layers, and a boundary between adjacent films or layers may or may not be clear and may be established based on physical, chemical, and/or any other characteristics, formation processes or sequence, and/or functions or purposes of the adjacent films or layers.

In this disclosure, “containing a Si—N bond” may refer to being characterized by a Si—N bond or Si—N bonds, having a main skeleton substantially constituted by a Si—N bond or Si—N bonds, and/or having a substituent substantially constituted by a Si—N bond or Si—N bonds. A dielectric film containing a Si—N bond includes, but is not limited to, a SiN film and a SiON film, which have a dielectric constant of about 2 to 10, typically about 4 to 8.

Further, in this disclosure, the article “a” or “an” refers to a species or a genus including multiple species unless specified otherwise. The terms “constituted by” and “having” refer independently to “typically or broadly comprising”, “comprising”, “consisting essentially of”, or “consisting of” in some embodiments. Also, in this disclosure, any defined meanings do not necessarily exclude ordinary and customary meanings in some embodiments. Additionally, in this disclosure, any two numbers of a variable can constitute a workable range of the variable as the workable range can be determined based on routine work, and any ranges indicated may include or exclude the endpoints. Additionally, any values of variables indicated (regardless of whether they are indicated with “about” or not) may refer to precise values or approximate values and include equivalents, and may refer to average, median, representative, majority, etc. in some embodiments.

In the present disclosure where conditions and/or structures are not specified, the skilled artisan in the art can readily provide such conditions and/or structures, in view of the present disclosure, as a matter of routine experimentation. In all of the disclosed embodiments, any element used in an embodiment can be replaced with any elements equivalent thereto, including those explicitly, necessarily, or inherently disclosed herein, for the intended purposes. Further, the present invention can equally be applied to apparatuses and methods. The embodiments will be explained with respect to preferred embodiments. However, the present invention is not limited to the preferred embodiments.

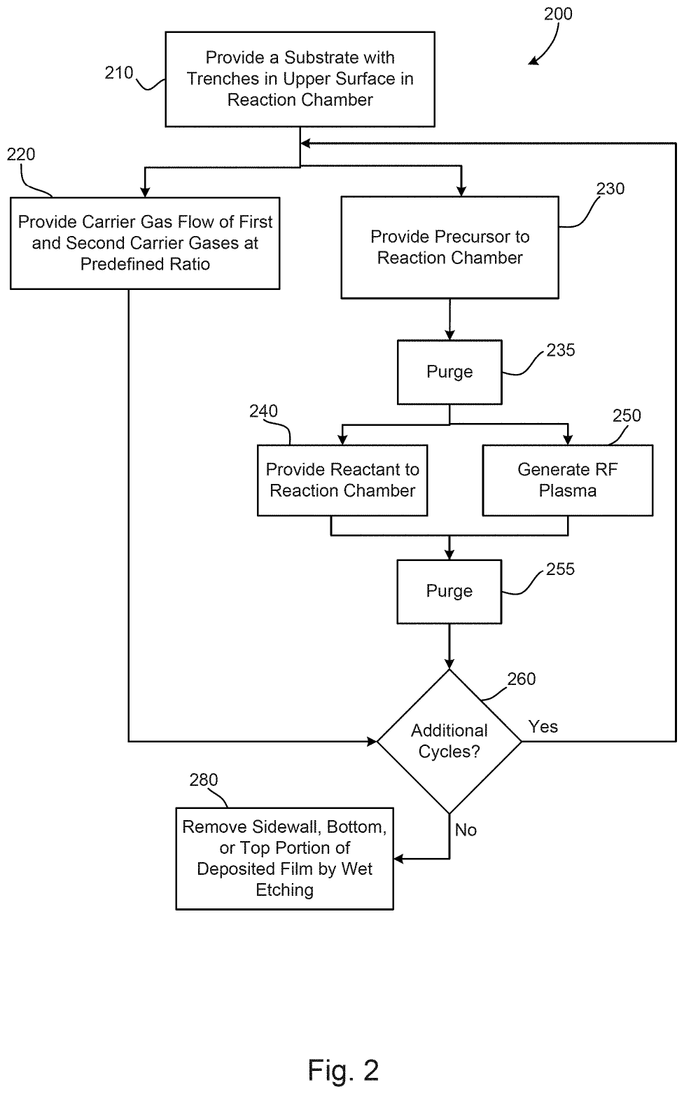

FIG. 2 illustrates one exemplary fabrication process 200 for a layered structure according to the present description. The method 200 may be adapted such that the layered structure includes a dielectric film containing a Si—N bond in a trench or pattern formed in an upper surface of a substrate, and, as noted above, the method 200 is particularly suited for forming this film such that it is a TS-SiN film to facilitate wet etching to selectively remove the film (or portions thereof) from the sidewall portions of the trench, from the bottom portions of the trench and/or from the top portions of the substrate. Particularly, the deposition portions of the fabrication process may be carried out such that the portions of the thin film on the sidewalls has a higher WER than portions of the thin film on the bottom portions of the trench, which in turn may have the same or a higher WER than portion of the thin film on the top portions of the trench or pattern.

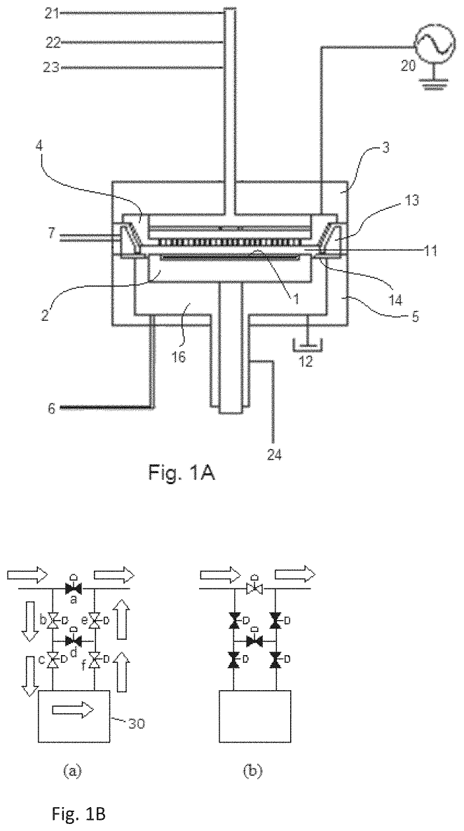

The method 200 includes step 210 that involves providing a substrate in a reaction chamber. The substrate has one or more trenches on an upper surface, and the substrate is placed on a substrate support or lower electrode such that it is placed in parallel to two electrodes of the reaction chamber to facilitate it being bombarded or in contact with RF generated plasma To this end, the reaction chamber may be configured as a plasma deposition apparatus such as one adapted to perform PECVD or, more preferably in some cases, PEALD as shown with the apparatus of FIG. 1A (described in detail below).

The method 200 continues concurrently (or at least partially concurrently with step 220 and steps 230 to 260. In step 220, the deposition apparatus or system is operated to provide a carrier gas flow into the chamber (and over the substrate upper surface). The carrier gas flow is made up of first and second carrier gases at a predefined ratio (X=first carrier gas/second carrier gas in the carrier gas flow rate). In one useful embodiment, the first carrier gas is argon (Ar) and the second carrier gas is nitrogen (N₂), and the gas flow rate is provided continuously (or substantially so) during the performance of steps 230 to 260 (i.e., deposition of the thin film of SiN or other thin film material). The ratio may be 0 to 4 in some cases or may be greater than 4 in others to achieve a TS-SiN film with desired WERs in the sidewall portions, bottom portions, and top portions of the film material. In other useful cases, the ratio is 4 while other useful results have been obtained with a ratio of 0.36 and of ratios less than 0.3.

The method 200 includes step 230 which involves providing a precursor to the reaction chamber such as DCS while some implementations of the method may utilize one or more precursors selected from a silicon precursor including one or more of a silane, a halogensilane, and an organosilane. Exemplary halogensilanes include one or more of dichlorosilane, diiodo silane, hexachlorodisilane, octachlorotrisilane, dibromo silane, tribromo silane, trichlorosilane (HSiCl₃), chlorosilane (H₃SiCl), silicon tetrachloride (SiCl₄), bromosilane (H₃SiBr), triiodo silane (HSil₃), iodosilane (H₃Sil), diiiodosilane (H₂Si₂l₄), H₄Si₂l₂, and H₅Si₂l. Exemplary organosilanes include one or more of an aminosilane and a heterosilane. By way of particular examples, the silicon precursor can include one or more of tris(dimethylamino)silane, bis(tert-butylamino)silane, di(sec-butylamino)silane, trisilylamine, neopentasilane, bis(dimethylamino)silane, (dimethylamino)silane(DMAS), bis(diethylamino)silane (BDEAS), bis(ethylmethylamino)silane (BEMAS), tetrakis(dimethylamino)silane (TKDMAS), trimethylsilane (SiH(CH₃)₃), tetramethylsilane (Si(CH₃)₄), silane, tetra(ethoxy)silane (TEOS, Si(OC₂H₅)₄), tris(tert-butoxy)silanol (TBOS), tris(tert-pentoxy)silanol (TPSOL), and dimethyldichlorosilane (Si(OC₂H₅)₄, Si(CH₃)₂(OCH₃)₂). This step 230 may have a range of durations such as 0.1 to 10 seconds or the like, with 0.5 seconds used in some cases. Step 230 is followed by purging at step 235 for a duration that again may vary such as 0.1 to 10 seconds with 0.5 seconds being adequate in many cases. The deposition portion of the method 200 continues with concurrent (or at least partial overlapping) performance of steps 240 and 250 involving providing a reactant into the reaction chamber and generating an RF plasma. The reactant may take a number of forms to practice the method 200 with ammonia (NH₃) used in some exemplary embodiments while others may use one or more from the group consisting of H₂, NH₃, N₂H₄, and N₂H₂. The duration of steps 240 and 250 may also vary such within the range of 1 to 5 seconds with 1.5 second duration being used in some implementations. A purge of the reactant occurs at step 255 (e.g., for a duration of 0.1 to 3 seconds with 0.2 seconds being adequate in some embodiments). A step 260 the control algorithm determines whether additional cycles (with steps 230 to 255 being part of a single cycle of a cyclic plasma deposition process) are needed to deposition a film with a desired thickness or if the desired thickness is achieved (number of predefined cycles has been carried out). If more cycles are determined to be required, the method 200 continues at 230 (and with continuing step 220).

Once the proper number of cycles are completed as determined at 260, the method 200 continues with step 280. In this step, the substrate is removed from the reaction chamber, and wet etching is performed (such as with HF liquid or the like) to remove all or fractional amounts of the portion of the thin film on the sidewalls of the trench(es), of the thin film on the bottom of the trench(es), and of the thin film on the top of the trench(es). This selective etching is possible because the thin film formed by performance of steps 220-260 is a film with etch selectivity that provides differing WERs at these three differing topological locations within the substrate's upper surface.

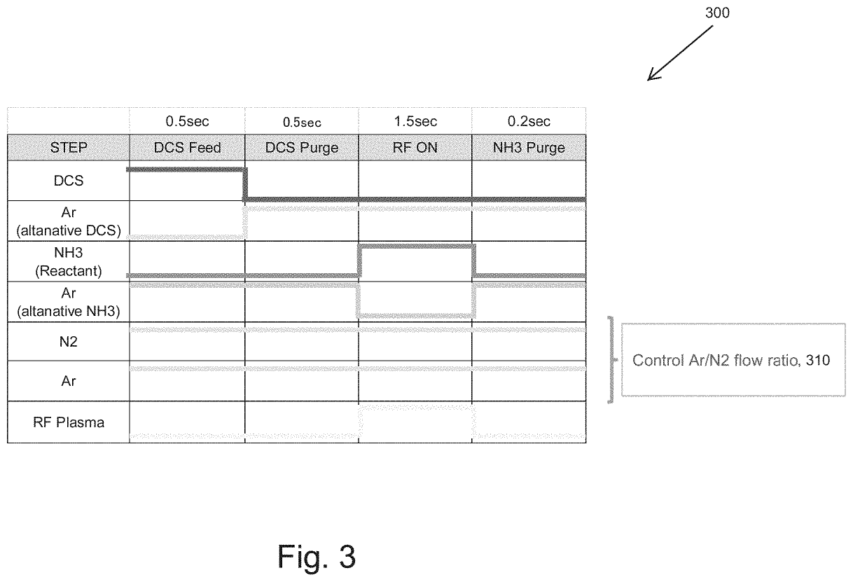

FIG. 3 is a graph 300 illustrating steps within a cycle of a thin film deposition of the present description such as the process of FIG. 2. As shown, all the steps of the cycle are performed while a combined flow of argon and nitrogen is provided to a reaction chamber in which a substrate is positioned. As noted at 310, the flow ratio of argon to nitrogen is controlled, and this may be done in a manner as discussed above to achieve desired differing WERs in the a deposited film on differing topologies of the trench or pattern.

While this flow ratio is controlled, the deposition steps include feeding (or 0.5 seconds) a precursor in the form of DCS to the chamber followed by a purge (for 0.5 seconds) of the precursor. The steps of deposition then includes powering on RF power source to generate an RF plasma in the reaction chamber while concurrently contacting the substrate upper surface with a reactant in the form of NH₃. This step is followed by a purge (for 0.2 seconds) of the reactant from the chamber.

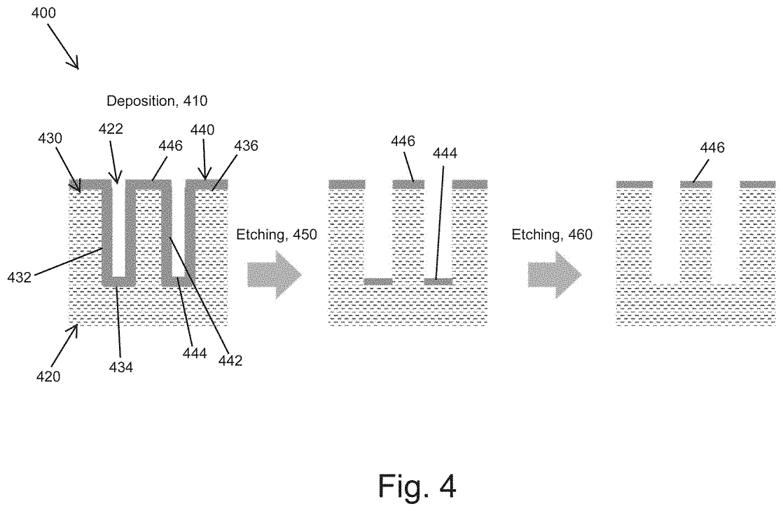

FIG. 4 is a schematic representation of deposition and etch processes 400 for fabricating a layered structure with a thin film formed to have differing wet etch rates (WERs) in differing topological areas. In step 410, deposition of a thin film, e.g., a TS-SiN film, 440 on a substrate 420. As shown, the substrate has trenches 422 in its upper surface 430. The trenches 422 are defined by sidewalls 432, bottom surfaces 434 between adjacent and facing sidewalls 432, and top surface 436 at upper edges of each of the sidewalls 432. The deposition 410 is performed (e.g., with control of the Ar/N₂ ratio) to simultaneously form the thin film 440 with WERs that differ for portions 442 on the sidewalls 432, for portions 444 on the bottom surfaces 434, and for portions 446 on the top surfaces 436 of the trenches 422.

As noted above, the sidewall portions 442 typically have the highest WER while the WER for the bottom portions 444 may be at least somewhat higher than the WER for top portions 446 of the thin film (e.g., the TS-SiN film) 440. As a result, the process 400 may follow the deposition 410 with a first wet etching cycle (or wet etching for a first time period) 450. Due to the higher WER of the thin film 440 in the sidewall portions 442, these are etched away or removed while the portions of the thin film 440 in the bottom and top portions 444 and 446 remain in the layered structure. Due to the higher WER of the thin film 440 in the bottom portions 444, though, a second wet etching cycle (or wet etching for a second time period) 460 may be carried out as shown in FIG. 4 to selectively remove the bottom portions 444 of the thin film 440 such that a majority or at least a useful thickness of material remains in the top portion 446 of the thin film 440 in the layered structure. The top portion 446 may be used as a hardmask.

The deposition process cycles described herein can be performed using any suitable apparatus including an apparatus illustrated in FIG. 1A, for example. FIG. 1A is a schematic view of a PEALD apparatus, desirably in conjunction with controls programmed to conduct the sequences described herein, usable in some embodiments of the present invention. In this figure, by providing a pair of electrically conductive flat-plate electrodes 4, 2 in parallel and facing each other in the interior 11 (reaction zone) of a reaction chamber 3, applying HRF power (13.56 MHz or 27 MHz) 20 to one side, and electrically grounding the other side 12, a plasma is excited between the electrodes. A temperature regulator is provided in a lower stage 2 (the lower electrode), and a temperature of a substrate 1 placed thereon is kept constant at a given temperature. The upper electrode 4 serves as a shower plate as well, and reactant gas (and noble gas) and precursor gas are introduced into the reaction chamber 3 through a gas line 21 and a gas line 22, respectively, and through the shower plate 4.

Additionally, in the reaction chamber 3, a circular duct 13 with an exhaust line 7 is provided, through which gas in the interior 11 of the reaction chamber 3 is exhausted. Additionally, a dilution gas is introduced into the reaction chamber 3 through a gas line 23. Further, a transfer chamber 5 disposed below the reaction chamber 3 is provided with a seal gas line 24 to introduce seal gas into the interior 11 of the reaction chamber 3 via the interior 16 (transfer zone) of the transfer chamber 5 wherein a separation plate 14 for separating the reaction zone and the transfer zone is provided (a gate valve through which a wafer is transferred into or from the transfer chamber 5 is omitted from this figure). The transfer chamber is also provided with an exhaust line 6. In some embodiments, the deposition of multi-element film and surface treatment are performed in the same reaction space, so that all the steps can continuously be conducted without exposing the substrate to air or other oxygen-containing atmosphere. In some embodiments, a remote plasma unit can be used for exciting a gas.

In some embodiments, in the apparatus depicted in FIG. 1A, the system of switching flow of an inactive gas and flow of a precursor gas illustrated in FIG. 1B (described below) can be used to introduce the precursor gas in pulses without substantially fluctuating pressure of the reaction chamber. In some embodiments, a dual chamber reactor (two sections or compartments for processing wafers disposed close to each other) can be used, wherein a reactant gas and a noble gas can be supplied through a shared line whereas a precursor gas is supplied through unshared lines.

A skilled artisan will appreciate that the apparatus includes one or more controller(s) (not shown) programmed or otherwise configured to cause the deposition and reactor cleaning processes described elsewhere herein to be conducted. The controller(s) are communicated with the various power sources, heating systems, pumps, robotics, and gas flow controllers or valves of the reactor, as will be appreciated by the skilled artisan.

In the above process sequences, the precursor may be supplied in a pulse using a carrier gas (e.g., the carrier gas described herein with a desired Ar/N₂ ratio) which is continuously supplied. This can be accomplished using a flow-pass system (FPS) wherein a carrier gas line is provided with a detour line having a precursor reservoir (bottle), and the main line and the detour line are switched, wherein when only a carrier gas is intended to be fed to a reaction chamber, the detour line is closed, whereas when both the carrier gas and a precursor gas are intended to be fed to the reaction chamber, the main line is closed and the carrier gas flows through the detour line and flows out from the bottle together with the precursor gas. In this way, the carrier gas can continuously flow into the reaction chamber and can carry the precursor gas in pulses by switching the main line and the detour line. FIG. 1B illustrates a precursor supply system using a flow-pass system (FPS) according to an embodiment of the present invention (black valves indicate that the valves are closed). As shown in (a) in FIG. 1B, when feeding a precursor to a reaction chamber (not shown), first, a carrier gas such as Ar (or He) flows through a gas line with valves b and c, and then enters a bottle (reservoir) 30. The carrier gas flows out from the bottle 30 while carrying a precursor gas in an amount corresponding to a vapor pressure inside the bottle 30, and flows through a gas line with valves f and e, and is then fed to the reaction chamber together with the precursor. In the above, valves a and d are closed. When feeding only the carrier gas (noble gas) to the reaction chamber, as shown in (b) in FIG. 1B, the carrier gas flows through the gas line with the valve a while bypassing the bottle 30. In the above, valves b, c, d, e, and f are closed.

The precursor may be provided with the aid of a carrier gas. Since ALD is a self-limiting adsorption reaction process, the number of deposited precursor molecules is determined by the number of reactive surface sites and is independent of precursor exposure after saturation, and a supply of the precursor is such that the reactive surface sites are saturated thereby per cycle. A plasma for deposition may be generated in situ, for example, in an ammonia gas that flows continuously throughout the deposition cycle. In other embodiments the plasma may be generated remotely and provided to the reaction chamber.

As mentioned above, each pulse or phase of each deposition cycle is preferably self-limiting. An excess of reactants is supplied in each phase to saturate the susceptible structure surfaces. Surface saturation ensures reactant occupation of all available reactive sites (subject, for example, to physical size or “steric hindrance” restraints) and thus ensures excellent step coverage. In some embodiments the pulse time of one or more of the reactants can be reduced such that complete saturation is not achieved and less than a monolayer is adsorbed on the substrate surface.

In some embodiments, the plasma used in the deposition process is a capacitively coupled plasma (CCP) which is excited by applying RF power to one of the two electrodes in the reaction chamber. Further, in some embodiments, inductively coupled plasma (ICP), electron cyclotron resonance (ECR) plasma, microwave surface wave plasma, helicon wave plasma, and the like can be used as the plasma, wherein bias voltage is applied to the electrodes as necessary to increase dc bias voltage between the plasma and electrode.

In some embodiments, the plasma is a plasma of Ar, N₂, and/or O₂ or other atoms which have an atomic number higher than hydrogen or helium. In some embodiments, the trench has a width of 10 to 50 nm (typically 15 to 30 nm) (wherein when the trench has a length substantially the same as the width, it is referred to as a hole/via, and a diameter thereof is 10 to 50 nm), a depth of 30 to 200 nm (typically 50 to 150 nm), and an aspect ratio of 3 to 20 (typically 3 to 10).

In some embodiments, the dielectric film can be used as an etching stopper, low-k spacer, or gap-filler. For example, when only the sidewall portion is left, the portion can be used as a spacer for spacer-defined double patterning (SDDP), or when only the top/bottom portion is left, the portion can be used as a mask used for solid-state doping (SSD) of a sidewall layer exclusively.

In some embodiments, the layered structure fabrication process includes placing a substrate having a trench in its upper surface between the electrodes and then depositing the dielectric film on the substrate by plasma-enhanced atomic layer deposition (PEALD) using dichlorosilane as a precursor or precursor gas and ammonia as a reactant gas. The plasma may be a capacitively coupled plasma (CCP) which is excited by applying RF power to one of the two electrodes in each cycle of the PEALD. A carrier gas including a predefined ratio of argon to nitrogen is provided continuously through the deposition process to form a TS-SiN film so that the wet etching removes the sidewall portion of the dielectric film selectively relative to the bottom and top portion of the dielectric film and also removes the bottom portion of the dielectric film selectively relative to the top portion (as each of these three portions of the film may have differing WERs). In the above, the film having etching selectivity is formed as the film is depositing.

In some embodiments, the deposition cycle may be performed by PEALD, and it may be useful to describe one cycle of and the conditions under which a working example or experiment was performed to deposit a layered structure with etch selectivity as described herein and then performing wet etching. The deposition cycle may include the steps shown in graph 300 of FIG. 3, and the conditions of the deposition include performing precursor feed for 0.5 seconds by providing DCS at 1000 sccm. During this precursor feed and other cycle steps, argon is provided at 3000 sccm and nitrogen at 750 sccm to control the Ar/N₂ flow ratio at 4.0 in experimental run. Other conditions include BTL 1/BFL 2 Ar at 2000/2000 sccm, Seal N₂ at 2000 sccm, reaction chamber pressure at 400 Pa, HRF set at 140 W, SUS/SHD/Wall Temperatures of 450/200/150° C., and a gap of 13 mm. Wet etching was then performed with dilute HF (e.g., HF: H₂0=1: 500) with a dipping time of 120 seconds. In this working example, etching results similar to those shown FIG. 4 after the second etching 460 were achieved with only the SiN film 446 in the top portions 436 of the trenches 422 remaining.

Additional experiments were carried out with additional useful results. The conditions described above were utilized except the flow ratio of argon to nitrogen was set at 4.0 (1500 sccm Ar to 380 sccm N₂), at greater than 4.0 (1500 sccm Ar to 0 sccm N₂), at 0.36 (1000 sccm Ar to 2760 sccm N₂), and at less than 0.3 (0 sccm Ar to 3750 N₂). The results (e.g., as measured by STEM) were that as deposited: (1) with the ratio at 4.0, after deposition the top portion of the film had a thickness of 5.29 nm, the side portion had a thickness of 3.31, and the bottom portion had a thickness of 4.5 and after wet etching (with DHF for 60 seconds) these values had become 5.29 nm, 0 nm, and 3.93 nm indicating a top WER (in nm/min) of 0, a sidewall WER greater than 3.31, and a bottom WER of 0.60; (2) with the ratio greater than 4.0, after deposition the top portion of the film had a thickness of 5.54 nm, the side portion had a thickness of 3.51, and the bottom portion had a thickness of 4.86 and after wet etching (with DHF for 60 seconds) these values had become 5.33 nm, 0 nm, and 4.46 nm indicating a top WER (in nm/min) of 0.21, a sidewall WER greater than 3.51, and a bottom WER of 0.40; (3) with the ratio at 0.36, after deposition the top portion of the film had a thickness of 5.42 nm, the side portion had a thickness of 3.72, and the bottom portion had a thickness of 4.83 and after wet etching (with DHF for 60 seconds) these values had become 4.75 nm, 0 nm, and 3.14 nm indicating a top WER (in nm/min) of 0.67, a sidewall WER greater than 3.72, and a bottom WER of 1.68; and (4) with the ratio greater of less than 0.3, after deposition the top portion of the film had a thickness of 5.34 nm, the side portion had a thickness of 4.13, and the bottom portion had a thickness of 4.86 and after wet etching (with DHF for 60 seconds) these values had become 5.21 nm, 0 nm, and 3.02 nm indicating a top WER (in nm/min) of 0.13, a sidewall WER greater than 4.13, and a bottom WER of 1.85. Selectivities (or the ratio of top WER to bottom WER) in these four test runs were 0, 0.52, 0.40, and 0.07 by controlling the Ar/N₂ flow ratio during PEALD deposition of the SiN film to form a layered structure.

Benefits, other advantages, and solutions to problems have been described herein with regard to specific embodiments. However, the benefits, advantages, solutions to problems, and any elements that may cause any benefit, advantage, or solution to occur or become more pronounced are not to be construed as critical, required, or essential features or elements of the disclosure.

Furthermore, the described features, advantages, and characteristics of the disclosure may be combined in any suitable manner in one or more embodiments. One skilled in the relevant art will recognize that the subject matter of the present application may be practiced without one or more of the specific features or advantages of a particular embodiment. In other instances, additional features and advantages may be recognized in certain embodiments that may not be present in all embodiments of the disclosure. Further, in some instances, well-known structures, materials, or operations are not shown or described in detail to avoid obscuring aspects of the subject matter of the present disclosure. No claim element is intended to invoke 35 U.S.C. 112(f) unless the element is expressly recited using the phrase “means for.”

Moreover, where a phrase similar to “at least one of A, B, and C” is used in the claims, it is intended that the phrase be interpreted to mean that A alone may be present in an embodiment, B alone may be present in an embodiment, C alone may be present in an embodiment, or that any combination of the elements A, B and C may be present in a single embodiment; for example, A and B, A and C, B and C, or A, B, and C. In some cases, “at least one of item A, item B, and item C” may mean, for example, without limitation, two of item A, one of item B, and ten of item C; four of item B and seven of item C; or some other suitable combination.

All ranges and ratio limits disclosed herein may be combined. Unless otherwise indicated, the terms “first,” “second,” etc. are used herein merely as labels, and are not intended to impose ordinal, positional, or hierarchical requirements on the items to which these terms refer. Moreover, reference to, e.g., a “second” item does not require or preclude the existence of, e.g., a “first” or lower-numbered item, and/or, e.g., a “third” or higher-numbered item.

Although exemplary embodiments of the present disclosure are set forth herein, it should be appreciated that the disclosure is not so limited. For example, although reactor systems are described in connection with various specific configurations, the disclosure is not necessarily limited to these examples. Various modifications, variations, and enhancements of the system and method set forth herein may be made without departing from the spirit and scope of the present disclosure.

What is claimed is:

1. A method of fabricating a layer structure, comprising:
providing a substrate in a reaction chamber, wherein the substrate comprises on an upper surface a trench with a top surface, a bottom surface, and sidewalls;
providing a carrier gas flow to the reaction chamber, wherein the carrier gas flow comprises a first carrier gas and a second carrier gas;
during the providing of the carrier gas flow, forming a dielectric film containing a Si—N bond on the upper surface of the substrate; and
after the forming of the dielectric film, removing with etching at least a portion of the dielectric film on at least one of the sidewalls, the top surface, and the bottom surface, wherein the etching has a first rate for the portion of the dielectric film on the sidewalls, a second rate for the portion of the dielectric film on the bottom surface, and a third rate for the portion of the dielectric film on the top surface and wherein the first, second, and third rates for the etching are defined at least in part by a ratio of the first carrier gas to the second carrier gas.

2. The method of claim 1, wherein the forming of the dielectric film comprises a cyclic plasma deposition process.

3. The method according to claim 1, wherein the cyclic plasma deposition process comprises PEALD or PECVD.

4. The method according to claim 1, wherein a cycle of the cyclic plasma deposition process includes contacting the upper surface of the substrate with a precursor selected from the group consisting of H₂SiCl₂, hexachlorodisilane, trichlorosilane, trichlorosilane (HSiCl₃), and chlorosilane (H₃SiCl) and contacting the upper surface of the substrate with a reactant selected from the group consisting of NH₃, N₂H₄, and N₂H₂.

5. The method according to claim 1, wherein the first carrier gas comprises argon (Ar) and the second carrier gas comprises nitrogen (N₂).

6. The method according to claim 1, wherein the etching comprises wet etching and wherein the first rate for the etching for the portion of the dielectric film on the sidewalls is greater than the second rate for the etching for the portion of the dielectric film on the bottom surface and wherein the second rate for the etching for the portion of the dielectric film on the bottom surface is greater than the third rate for the etching for the portion of the dielectric film on the top surface.

7. The method according to claim 1, wherein the ratio of the first carrier gas to the second carrier gas is in the range of 0 to 4.

8. The method according to claim 7, wherein the ratio of the first carrier gas to the second carrier gas is less than 0.3.

9. The method according to claim 7, wherein the ratio of the first carrier gas to the second carrier gas is 0.36.

10. The method according to claim 7, wherein the ratio of the first carrier gas to the second carrier gas is 4.

11. The method according to claim 1, wherein the ratio of the first carrier gas to the second carrier gas is greater than 4.

12. A method of fabricating a layer structure, comprising:
providing a substrate in a reaction chamber, wherein the substrate comprises on an upper surface a trench with a top surface, a bottom surface, and sidewalls;
forming a film comprising SiN on the upper surface of the substrate using a cyclical plasma deposition process, wherein the cyclical plasma deposition process includes providing a flow of argon and nitrogen to the reaction chamber at a predefined flow ratio; and
after the forming of the film, removing with etching at least a portion of the film on at least one of the sidewalls, the top surface, and the bottom surface, wherein the etching has a first rate for the portion of the film on the sidewalls, a second rate for the portion of the film on the bottom surface, and a third rate for the portion of the film on the top surface and wherein the first, second, and third rates for the etching differ.

13. The method of claim 12, wherein the cyclic plasma deposition process comprises PEALD.

14. The method according to claim 12, wherein a cycle of the cyclic plasma deposition process includes contacting the upper surface of the substrate with a precursor selected from the group consisting of H₂SiCl₂, hexachlorodisilane, trichlorosilane, trichlorosilane (HSiCl₃), and chlorosilane (H₃SiCl) and contacting the upper surface of the substrate with a reactant selected from the group consisting of H₂, NH₃, N₂H₄, and N₂H₂.

15. The method according to claim 12, wherein the first rate for the etching for the portion of the film on the sidewalls is greater than the second rate for the etching for the portion of the film on the bottom surface and wherein the second rate for the etching for the portion of the film on the bottom surface is greater than the third rate for the etching for the portion of the film on the top surface.

16. The method according to claim 12, wherein the predefined ratio is in the range of 0 to 4.

17. The method according to claim 12, wherein the predefined ratio is greater than 4.

18. A method of fabricating a layer structure, comprising:
providing a substrate in a reaction chamber, wherein the substrate comprises on an upper surface a trench with a top surface, a bottom surface, and sidewalls;
forming a TS-Si film on the upper surface of the substrate using a PEALD process, wherein the PEALD process includes providing a flow of argon and nitrogen to the reaction chamber at a predefined flow ratio, wherein the predefined flow ratio is selected such that the wet etch ratio (WER) for the film on the sidewalls is greater than the WER for the film on the bottom surface and the WER for the film on the top surface; and
after the forming of the film, removing with wet etching the film on the sidewalls while retaining at least a portion of the thin film on the top surface.

19. The method of claim 18, wherein etch selectivity as measured by a ratio of the WER for the film on the top surface to the WER for the film on the bottom surface is in the range of 0 to 0.8.

20. The method according to claim 18, wherein a cycle of the PEALD process includes contacting the upper surface of the substrate with a precursor selected from the group consisting of H₂SiCl₂, hexachlorodisilane, trichlorosilane, trichlorosilane (HSiCl₃), and chlorosilane (H₃SiCl) and contacting the upper surface of the substrate with a reactant selected from the group consisting of H₂, NH₃, N₂H₄, and N₂H₂.
